(19) United States
(12) Patent Application Publication
(10) Pub. No.: US 2007/0187818 A1
(43) Pub. Date: Aug. 16, 2007

(54) Package on package design a combination of laminate and tape substrate

(75) Inventor: Kevin Peter Lyne, Fairview, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/543,536

(22) Filed: Oct. 5, 2006

Related U.S. Application Data
(60) Provisional application No. 60/773,719, filed on Feb. 15, 2006.

(51) Int. Cl. H01L 21/44

(52) U.S. Cl. 257/734; 438/612

(57) ABSTRACT

In a method and system for fabricating a semiconductor device (100) having a package-on-package structure, a bottom laminate substrate (BLS) (130) is formed to include interconnection patterns (170) coupled to a plurality of conductive bumps (130). A top substrate (TS) (140) is formed as a receptor to mount a top package (110). The TS (140) is formed by a polyimide tape (142) affixed to a metal layer (144). A laminate window frame (LWF) (150), which may be fabricated as a part of the BLS (130), is fabricated along a periphery of the BLS (130) to form a center cavity (160). The center cavity (160) that is enclosed by the BLS (130), the LWF (150) and the TS (140) houses at least one die (134, 136) attached to the BLS (130). The interconnection patterns (170, 172) formed in the BLS (130) and the LWF (150) provide the electrical coupling between the metal layer (144), the at least one die (134, 136), and the plurality of conductive bumps (130).

### CROSS REFERENCE TO RELATED APPLICATIONS

This application is related to U.S. Provisional Application No. 60/773,719 filed Feb. 15, 2006, entitled ‘Package On Package Design A Combination Of Laminate And Tape Substrate, With Back-To-Back Die Combination’, which is hereby incorporated herein in its entirety.

### BACKGROUND

The present invention is related in general to the field of semiconductor device assembly and packaging, and more specifically to fabricating integrated circuit (IC) devices having three dimensional packaging.

It is well known that the consumers of the next generation electronic devices are demanding increased functions and features that are packed in a smaller size, consuming less power, and costing less than the earlier generation. Semiconductor device manufacturers are responding by incorporating improved three dimensional packaging technologies such as systems in package (SiP), Multi-Chip Packages (MCPs), Package-on-Package (PoP), and similar others that provide vertical stacking of one or more dies and/or packages that are integrated to operate as one semiconductor device.

PoP typically includes two semiconductor packages that are stacked on top of one another, and may be commonly used in products desiring efficient access to memory while reducing size, such as cellular telephones. Thus, PoP is a well known packaging technique to vertically combine two IC chips such as a logic chip, and a memory chip electrically coupled by ball grid arrays (BGAs) or similar other. However, many of the top packages are custom designed and often have unique and restricted footprints. As such, the top package may not be able to take advantage of low cost, commodity, off-the-shelf IC chips offering a standard, full matrix footprint.

### SUMMARY

Applicant recognizes an existing need for an improved method and system for fabricating a semiconductor device using a package-on-package (PoP) type packaging; and the need for providing a top package of the PoP that may be purchased as a commodity product having a full matrix footprint, absent the disadvantages found in the prior techniques discussed above.

The foregoing need is addressed by the teachings of the present disclosure, which relates to a system and method for packaging semiconductor devices. According to one embodiment, in a method and system for fabricating a semiconductor device having a package-on-package structure, a bottom laminate substrate (BLS) is formed to include interconnection patterns coupled to a plurality of conductive bumps. A top substrate (TS) is formed as a receptor to mount a top package. The TS is formed by a polyimide tape affixed to a metal layer. A laminate window frame (LWF), which may be fabricated as a part of the BLS, is fabricated along a periphery of the BLS to form a center cavity. The center cavity that is enclosed by the BLS, the LWF and the TS houses at least one die attached to the BLS. The interconnection patterns formed in the BLS and the LWF provide the electrical coupling between the metal layer, the at least one die and the plurality of conductive bumps.

In one aspect of the disclosure, a method for fabricating a semiconductor device having a package-on-package structure includes forming a bottom laminate substrate, which includes interconnection patterns coupled to a plurality of conductive bumps. A laminate window frame is formed along a periphery of the bottom laminate substrate to form a center cavity. At least one die is attached to the bottom laminate substrate within the center cavity by a die attach compound. The center cavity is filled with a polymeric compound to protect the at least one die. A top substrate is formed as a receptor to mount a top package. The top substrate, which includes a polyimide tape affixed to a metal layer by an adhesive layer, is connected to the laminate window frame by a conductive connection, thereby enabling electrical coupling between the top metal layer and the at least one die.

Several advantages are achieved by the method and system according to the illustrative embodiments presented herein. The embodiments advantageously provide an improved PoP structure by providing a thin and cost-effective polyimide tape as a receptor for mounting a top package. The center cavity of the bottom package is advantageously capable of housing one or more dies connected to the substrate via wire bonding and/or flip chip technologies. Vias or holes formed in the polyimide tape advantageously lower the profile of the top package by providing a recess for a solder ball of the top package while providing support for the edge of the solder ball. The top package may be advantageously purchased as a commodity memory package having a standard full matrix footprint. The improved PoP structure also advantageously accommodates top packages of varying body sizes while restricting the overall height.

### BRIEF DESCRIPTION OF THE DRAWINGS

FIG. 1A illustrates a simplified and schematic cross section of a semiconductor device having a package-on-package structure, according to an embodiment;

FIG. 1B additional details of a cross section of a bottom package of a semiconductor device described with reference to FIG. 1A, according to an embodiment;

FIG. 1C illustrates additional details of a cross section of a top package mounted on a bottom package of a semiconductor device described with reference to FIGS 1A and 1B, according to an embodiment; and

FIG. 2 is a flow chart illustrating a method for fabricating a semiconductor device having a package-on-package structure, according to an embodiment.

### DETAILED DESCRIPTION

Novel features believed characteristic of the present disclosure are set forth in the appended claims. The disclosure itself, however, as well as a preferred mode of use, various objectives and advantages thereof, will best be understood by reference to the following detailed description of an illustrative embodiment when read in conjunction with the accompanying drawings. The functionality of various circuits, devices or components described herein may be implemented as hardware (including discrete components, integrated circuits and systems-on-a-chip ‘SoC’), firmware (including application specific integrated circuits and programmable chips) and/or software or a combination thereof, depending on the application requirements. Similarly, the functionality of various mechanical elements, members, and/or components for forming modules, sub-assemblies and assemblies assembled in accordance with a structure for an apparatus may be implemented using various materials and coupling techniques, depending on the application requirements.

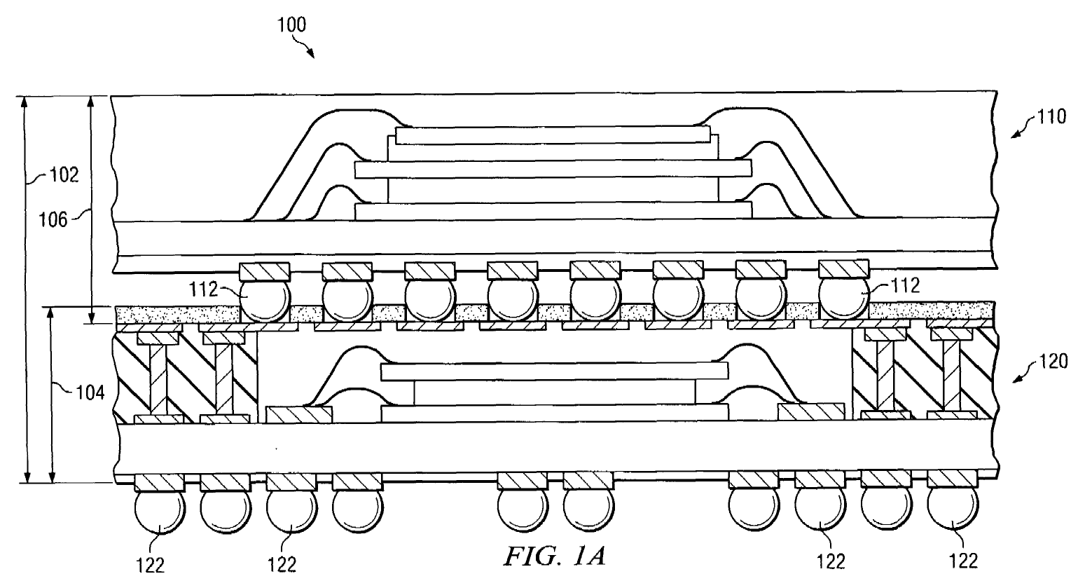

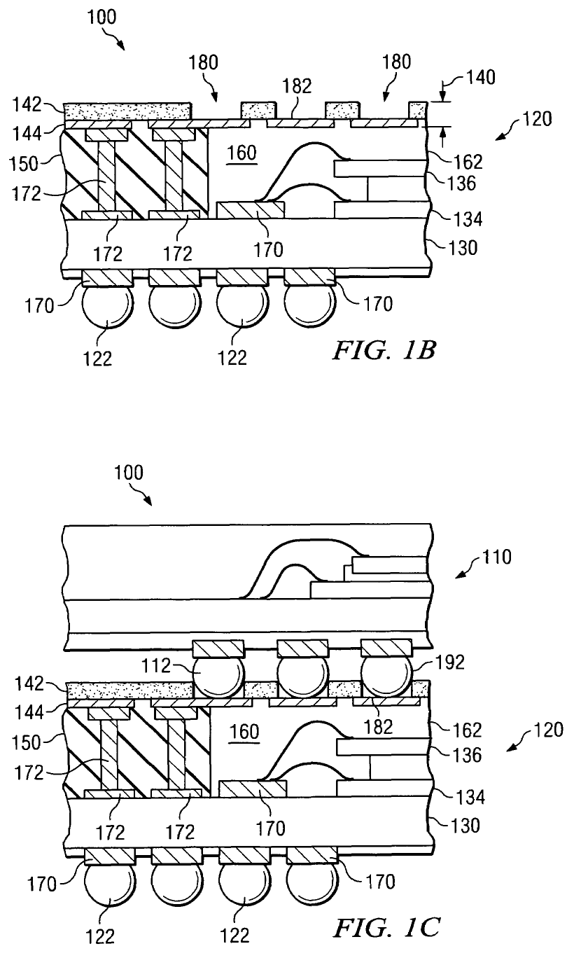

Traditional tools and methods for fabricating a semiconductor device having a PoP structure, may be limited by the constraints on the top package, the bottom package, and their interface. The constraints may include the bottom package being limited to one die, limited input/output (I/O) connections due to perimeter matrix footprint of the top package, and use of customized (non-commodity), more costly memory chips as the top package. This problem may be addressed by an improved system and method for fabricating a semiconductor device having a PoP structure. According to an embodiment, in a method and system for fabricating a semiconductor device having a package-on-package structure, a bottom laminate substrate (BLS) is formed to include interconnection patterns coupled to a plurality of conductive bumps. A top substrate (TS) is formed as a receptor to mount a top package. The TS is formed by a polyimide tape affixed to a metal layer. A laminate window frame (LWF), which may be fabricated as a part of the BLS, is fabricated along a periphery of the BLS to form a center cavity. The center cavity that is enclosed by the BLS, the LWF and the TS houses at least one die attached to the BLS. The interconnection patterns formed in the BLS and the LWF provide the electrical coupling between the metal layer, the at least one die and the plurality of conductive bumps. The fabrication of a semiconductor device having a PoP structure is described with reference to FIGS 1A, 1B, and 1C.

The following terminology may be useful in understanding the present disclosure. It is to be understood that the terminology described herein is for the purpose of description and should not be regarded as limiting.

Semiconductor Package (or Package)—A semiconductor package provides the physical and electrical interface to at least one integrated circuit (IC) or die for connecting the IC to external circuits. The package protects the IC from damage, contamination, and stress that result from factors such as handling, heating, and cooling.

Laminate and Tape Substrates—A substrate is an underlying material used to fabricate a semiconductor device. In addition to providing base support, substrates are also used to provide electrical interconnections between the IC chip and external circuits. Two categories of substrates that are used in ball grid array (BGA) packages for fabricating the semiconductor device include rigid and tape substrates. Rigid substrates are typically composed of a stack of thin layers or laminates, and are often referred to as laminate substrates. The laminate substrate is usually made of polymer-based material such as FR-4 or fiber-reinforced material such as BT (bismaleimide triazine). Tape substrates are typically composed of polymer material such as polyimide, and are often referred to as a polyimide tape substrate. The polyimide tape substrate, which typically includes a single metal layer, is generally cheaper and thinner compared to the multilayer laminate substrate.

Chip Footprint—A chip footprint (or simply the footprint) generally describes the properties of the chip's input/output connections or its contact elements. The properties typically include body size, pitch, number of connections, arrangement of the connections, type of the connection, and similar others. In some chips, space restrictions or constraints such as physical clearances, which may be desired due to a presence of another chip, may limit the arrangement of the contact elements along the peripheral rows of the chip. A chip having a partial or restricted footprint may be limited to having the contact elements arranged in the outer R (R being an integer, e.g., 2 or 3) rows, typically along the perimeter of the chip leaving a particular portion, e.g., a center portion, of the chip clear to accommodate the space restrictions or constraints. A chip having a full matrix footprint is typically free from space restrictions. The full matrix footprint includes contact elements arranged in a two dimensional array that occupies the entire bottom surface of the chip instead of the restricted arrangement. Actual number of contact elements included in the full matrix footprint may be equal to or less than R×C, where R=number of rows, and C=number of columns of the matrix, provided the reduction in the number of contact elements has not been made to comply with the space restrictions. As such, the chip having the full matrix footprint provides greater number of connections compared to the chip having the partial or restricted footprint.

FIG. 1A illustrates a simplified and schematic cross section of a semiconductor device 100 having a package-on-package structure, according to an embodiment. In the depicted embodiment, the semiconductor device 100 includes a top package 110 having a top ball grid array 112 mounted on a bottom package 120 having a bottom ball grid array 122. Although the top package 110 and the bottom package 120 are each shown with a ball grid array (BGA), other types of packages such as IC chips with leads or leadless, pin grid array (PGA), and land grid array (LGA) are also contemplated. In an embodiment, the bottom package 120 is an application specific integrated circuit (ASIC). In an embodiment, the top package 110 is a high volume, low cost, commodity memory multi-chip package (MCP) having a full matrix footprint, although other packages having other types of footprints are also contemplated. Thus, the top package 110 is not constrained by a restricted footprint that may have two rows of contact elements placed along the perimeter.

As described earlier, the chip footprint describes the properties of the chip's input/output connections or its contact elements. The properties typically include body size, pitch, number of connections, arrangement of the connections, type of the connection, and similar others. In some chips other than the top package 110, space restrictions or constraints such as physical clearances may limit the arrangement of the contact elements along the peripheral rows of the chip. A chip having a partial or restricted footprint may be limited to having the contact elements arranged in the outer R (R being an integer, e.g., 2 or 3) rows, typically along the perimeter of the chip leaving a particular portion, e.g., a center portion, of the chip clear to accommodate the space restrictions or constraints. A chip having a full matrix footprint, e.g., the top package 110, is typically free from space restrictions. The full matrix footprint includes contact elements arranged in a two dimensional array that occupies the entire bottom surface of the chip instead of the restricted arrangement. Actual number of contact elements included in the full matrix footprint may be equal to or less than R×C, where R=number of rows, and C=number of columns of the matrix, provided the reduction in the number of contact elements has not been made to comply with the space restrictions. As such, the chip having the full matrix footprint, e.g., the top package 110, provides greater number of connections compared to the chip having the partial or restricted footprint.

In the depicted embodiment, a body size of the top package 110 and the bottom package substantially match each other, e.g., 12×12 millimeters. In alternative embodiments, the body sizes may be smaller or larger relative to one another. For example, the body shape may resemble a rectangle having linear dimensions varying approximately between 5 millimeters and 20 millimeters. The body size of the top package 110 may vary by manufacturer, e.g., 11×11 millimeters, 10×10 millimeters, 10×13 millimeters, 10×12 millimeters, or similar other. A height 104 of the bottom package 120, and the bottom ball grid array 122 may vary between approximately 0.6 millimeters and at most equal to 0.7 millimeters. A height 106 of the top package 110, and the top ball grid array 112 may be at most equal to 0.8 millimeters. In an embodiment, a combined height 102 of the semiconductor device 100, which includes the heights 104 and 106 of the top package 110, the top ball grid array 112, the bottom package 120, and the bottom ball grid array 122 is at most equal to 1.4 millimeters. In an embodiment, the pitch of the bottom ball grid array 122 may be selected to be one of 0.4 or 0.5 millimeters, and the pitch of the top ball grid array 112 may be selected to be 0.5 or 0.8 millimeters. The bottom ball grid array 122 and the top ball grid array 112 each may also be referred to as a plurality of conductive bumps or solder balls. It is understood, that chip dimensions such as height, length, and width that are described herein are for exemplary purposes, and they may vary by application, and with technology. For example, a height of the semiconductor device 100 may be restricted to 1.4 millimeters in some applications such as thin cellular phones, whereas other applications of the device 100 may not impose such restrictions.

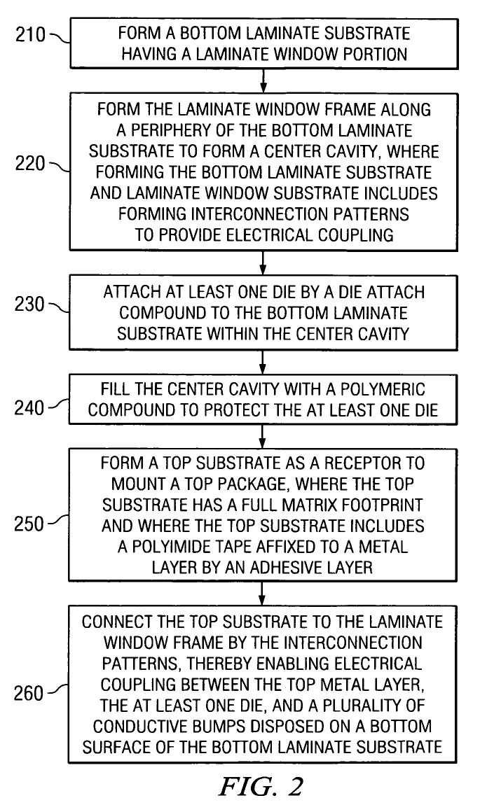

FIG. 1B illustrates additional details of a cross section of the bottom package 120 of the semiconductor device 100 described with reference to FIG. 1A, according to an embodiment. In an embodiment, the bottom package 120 includes a bottom laminate substrate 130 coupled to the bottom ball grid array 122 via the interconnection patterns 170, a top substrate 140 forming a receptor for the top package (not shown), and a laminate window frame 150 fabricated along a periphery of the bottom laminate substrate 130 to enclose a center cavity 160. In an embodiment, the laminate window frame 150 may be fabricated as part of the bottom substrate 130, or may added as a separate element during the assembly of the bottom package 120. Additional detail of the fabrication process of the semiconductor device 100 is described with reference to FIG. 2.

Referring back to FIG. 1B, the center cavity 160, which is completely enclosed by the bottom laminate substrate 130, the laminate window frame 150, and the top substrate 140 houses a first die 134 and a second die 136 attached to the bottom laminate substrate 130 by a die attach compound (not shown). In an exemplary, non-depicted embodiment, the center cavity 160 may include at least one die, where the at least one die includes one of one of a microprocessor, a digital signal processor, a radio frequency chip, a memory, a microcontroller, and a system-on-a-chip or a combination thereof. Although two dies, e.g., the first and second dies 134 and 136, are shown as being coupled to the interconnection patterns 170, other embodiments may include different number of dies and different connection techniques such as flip chip, or a combination of wire bond on one die and flip chip on another die. In an embodiment, the interconnection patterns 170 may include various electrical connection techniques such as a conductive adhesive, a thermo compression weld, a high melting point solder contact, a plurality of conductive traces, vias, metal planes, bond wires, metal lands, bond wire areas, and conductive pads, The bottom laminate substrate 130 includes the interconnection patterns 170 to electrically couple the first and second dies 134 and 136 to the bottom ball grid array 122 for connection to external circuits (not shown). In an embodiment, the center cavity 160 is filled with a polymeric compound 162 to protect the first and second dies 134 and 136, and to provide structural support for the top substrate 140. The polymeric compound 162 may be filled by an injection molding process.

In an embodiment, the bottom laminate substrate 130 and the laminate window frame 150 are rigid, multi-layer laminate substrates. As described earlier, rigid substrates are typically composed of a stack of thin layers or laminates, and are often referred to as laminate substrates. The laminate substrate is usually made of polymer-based material such as FR-4 or fiber-reinforced material such as BT (bismaleimide triazine). The thickness of the bottom laminate substrate 130 is approximately 150 micrometers, and the thickness of the laminate window frame 150 is approximately 300 micrometers, although thinner or thicker substrates may be possible. In an embodiment, the top substrate 140 includes a polyimide tape 142 affixed to a metal layer 144 by an adhesive layer (not shown). As described earlier, tape substrates are typically composed of polymer material such as polyimide, and are often referred to as a polyimide tape substrate. The polyimide tape substrate, which typically includes a single metal layer, is generally cheaper and thinner compared to the multilayer laminate substrate. A plurality of holes 180 are formed in the polyimide tape 142 to expose a plurality of metal lands 182 of the metal layer 144. The polyimide tape 142 is connected to the laminate window frame 150 by the interconnecting patterns 170 that may include one of a conductive adhesive, a thermo compression weld, a high melting point solder contact, and/or other electrical connection techniques.

FIG. 1C illustrates additional details of a cross section of the top package 110 mounted on the bottom package 120 of the semiconductor device 100 described with reference to FIGS 1A and 1B, according to an embodiment. Each one of the plurality of holes 180 that is formed in the polyimide tape 142 provides structural support for an edge 192 of each solder ball of the top ball grid array 112. In addition, each one of the plurality of holes 180 also advantageously provides recesses for the top ball grid array 112 to keep a lower profile, thereby lowering the profile or the height of the top package 110, and hence of the semiconductor device 100. Unlike use of a polymer collar to provide support, which is a well known technique used on some packages where a ring of polymeric material is placed on the surface of the substrate around the base of the ball, the plurality of holes 180 do not use a separate polymer collar to provide the support. The support provided by the plurality of holes 180 advantageously improves the reliability of the connection between the top package 110 and the bottom package 120, especially for the drop test. The plurality of holes 180, and hence the plurality of metal lands 182, are aligned with the top ball grid array 112 for mounting the top package 110. The top package 110 is mounted on the bottom package 120 using a tape automated bonding (TAB) process. The laminate window frame 150 includes additional ones of the interconnection patterns 170, e.g., interconnection patterns 172, which may include various electrical connection techniques such as a conductive adhesive, a thermo compression weld, a high melting point solder contact, a plurality of conductive traces, vias, metal planes, bond wires, metal lands, bond wire areas, and conductive pads, to electrically couple the metal layer 144 to the interconnection patterns 170 and 172, thereby providing interconnection between the top package 110 when mounted on the plurality of metal lands 182, the first and second dies 134 and 136, and the bottom ball grid array 122 for connection to external circuits (not shown).

In an embodiment, depending on the intended purpose of the device, the semiconductor device 100 may include one of one of a microprocessor, a digital signal processor, a radio frequency chip, a memory, a microcontroller, and a system-on-a-chip or a combination thereof.

FIG. 2 is a flow chart illustrating a method for fabricating a semiconductor device having a package-on-package structure, according to an embodiment. In a particular embodiment, FIG. 2 illustrates the process for fabricating the semiconductor device 100 described with reference to FIGS 1A, 1B, and 1C. At step 210, a bottom laminate substrate without the laminate window frame portion is formed. The formation of the bottom laminate substrate includes formation of interconnection patterns coupled to a plurality of conductive bumps. At step 220, the laminate window frame portion of the bottom laminate substrate is formed along a periphery of the bottom laminate substrate to form a center cavity. At step 230, at least one die is attached by a die attach compound to the bottom laminate substrate within the center cavity. At step 240, the center cavity is filled with a polymeric compound to protect the at least one die. At step 250, a top substrate is formed as a receptor to mount a top package. The top substrate includes a polyimide tape affixed to a metal layer by an adhesive layer. At step 260, the top substrate is connected to the laminate window frame by a conductive connection such as the interconnection patterns, thereby enabling electrical coupling between the top metal layer and the at least one die.

Various steps described above may be added, omitted, combined, altered, or performed in different orders. As described earlier with reference to FIG. 1B, the laminate window frame portion and the bottom laminate substrate, which may have different thicknesses, are formed from the same type of rigid, multi-layer laminate substrate. In an embodiment, the laminate window frame may be fabricated as part of the bottom substrate. In this embodiment, step 220 is deleted and merged with step 210. In an alternative embodiment, and as described herein, at step 220 the laminate window frame may be added or fabricated as a separate element during the assembly of the bottom package. As another example, forming the top substrate at step 250 may include an additional step of forming a plurality of holes in the polyimide tape to expose a plurality of metal lands of the metal layer.

Several advantages are achieved by the method and system according to the illustrative embodiments presented herein. The embodiments advantageously provide an improved PoP structure by providing a thin and cost-effective polyimide tape as a receptor for mounting a top package. The center cavity of the bottom package is advantageously capable of housing one or more dies connected to the substrate via wire bonding and/or flip chip technologies. Vias formed in the polyimide tape advantageously provide support for the edge of the solder ball that electrically couples the top and the bottom package. The support may advantageously improve the reliability of the solder connection. The top package may be advantageously purchased as a commodity memory package having a standard full matrix footprint. The improved PoP structure also advantageously accommodates top packages of varying body sizes while restricting the overall height.

Although illustrative embodiments have been shown and described, a wide range of modification, change and substitution is contemplated in the foregoing disclosure and in some instances, some features of the embodiments may be employed without a corresponding use of other features. Those of ordinary skill in the art will appreciate that the hardware and methods illustrated herein may vary depending on the implementation. For example, while certain aspects of the present disclosure have been described in the context of conventional mounting with wire bonding, those of ordinary skill in the art will appreciate that the processes disclosed are capable of being used for assembly of semiconductor devices using different types of mounting techniques.

The methods and systems described herein provide for an adaptable implementation. Although certain embodiments have been described using specific examples, it will be apparent to those skilled in the art that the invention is not limited to these few examples. The benefits, advantages, solutions to problems, and any element(s) that may cause any benefit, advantage, or solution to occur or become more pronounced are not to be construed as a critical, required, or an essential feature or element of the present disclosure.

The above disclosed subject matter is to be considered illustrative, and not restrictive, and the appended claims are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A semiconductor device comprising:
a bottom laminate substrate having a laminate window frame portion, wherein the laminate window frame portion is disposed along a periphery of the bottom laminate substrate;
a top substrate to mount a top package, the top package having a full matrix footprint, wherein the top substrate includes a polyimide tape affixed to a metal layer;
a center cavity enclosed between the bottom laminate substrate, the laminate window frame, and the top substrate to house at least one die; and
interconnection patterns included in the bottom laminate substrate, the laminate window frame and the center cavity, wherein the interconnection patterns provide electrical coupling between the metal layer, the at least one die, and a plurality of conductive bumps disposed on a bottom surface of the bottom laminate substrate.

2. The device of claim 1, wherein the top substrate includes:
a plurality of holes formed in the polyimide tape, the plurality of holes being arranged in a full matrix array pattern to match the full matrix footprint; and
a plurality of metal lands of the metal layer, wherein each one of the plurality of holes exposes a corresponding one of the plurality of metal lands, wherein the top package having the full matrix footprint is mounted on the plurality of metals lands.

3. The device of claim 2, wherein the plurality of holes reduces a profile of the top package by providing a recess for a contact element of the full matrix footprint.

4. The device of claim 2, wherein each one of the plurality of holes formed in the polyimide tape includes a wall surface, wherein the wall surface in contact with an edge of a contact element of the full matrix footprint provides support for the top package.

5. The device of claim 1, wherein the metal layer is bonded to the interconnection patterns included in the laminate window frame by one of a conductive adhesive, a thermo compression weld, and a high melting point solder contact.

6. The device of claim 1, wherein the at least one die is encapsulated by a polymeric compound, wherein the polymeric compound provides support to the top substrate.

7. The device of claim 1, wherein the interconnection patterns in the bottom laminate substrate, the laminate window frame and the center cavity include a plurality of conductive traces, vias, metal planes, bond wires, metal lands, and conductive pads.

8. The device of claim 1, wherein the at least one die is one of one of a microprocessor, a digital signal processor, a radio frequency chip, a memory, a microcontroller, and a system-on-a-chip or a combination thereof.

9. The device of claim 1, wherein the full matrix footprint includes contact elements arranged in a two dimensional matrix array on a bottom surface of the top package, wherein an arrangement of the contact elements is free from space restrictions.

10. The device of claim 1, wherein the device is less than or equal to 1.4 millimeters thick.

11. The device of claim 1, further comprising:
a bottom package, wherein the bottom package includes the bottom laminate substrate without the laminate window frame portion, the top substrate, the laminate window frame, and the center cavity, wherein the laminate window frame is disposed along the periphery of the bottom laminate substrate but is separate from the bottom laminate substrate.

12. The device of claim 1, wherein a height of the top package is less than or equal to 0.8 millimeters.

13. The device of claim 1, wherein a body size of the top package resembles a rectangle, wherein the rectangle has linear dimensions varying approximately between 5 millimeters and 20 millimeters.

14. A method for fabricating a semiconductor device having a package-on-package structure, the method comprising:
forming a bottom laminate substrate having a laminate window frame portion, wherein forming the bottom laminate substrates includes forming the laminate window frame disposed along a periphery of the bottom laminate substrate to form a center cavity, wherein forming the bottom laminate substrate and the laminate window frame includes forming interconnection patterns to provide electrical coupling;
attaching at least one die to the bottom laminate substrate within the center cavity;
filling the center cavity with a polymeric compound to protect the at least one die;
forming a top substrate as a receptor to mount a top package, the top package having a full matrix footprint, wherein the top substrate includes a polyimide tape affixed to a metal layer by an adhesive layer; and
connecting the top substrate to the laminate window frame by the interconnection patterns, thereby enabling electrical coupling between the top metal layer, the at least one die, and a plurality of conductive bumps disposed on a bottom surface of the bottom laminate substrate.

15. The method of claim 14, wherein the forming of the top substrate includes:
forming a plurality of holes in the polyimide tape to expose a plurality of metal lands of the metal layer, wherein the plurality of metal lands are arranged in a full matrix array to match the full matrix footprint.

16. The method of claim 14 further comprising:
mounting the top package on the top substrate, wherein the receptor includes exposed portions of the metal layer to electrically couple the top package with the at least one die.

17. The method of claim 14, wherein the at least one die is one of one of a microprocessor, a digital signal processor, a radio frequency chip, a memory, a microcontroller, and a system-on-a-chip or a combination thereof.

18. A semiconductor device having a package-on-package (PoP) structure, the device comprising:
a bottom package, wherein the bottom package includes:
a bottom laminate substrate having a laminate window frame portion, wherein the laminate window frame portion is disposed along a periphery of the bottom laminate substrate;
a top substrate having a polyimide tape affixed to a metal layer, wherein the polyimide tape includes a plurality of holes to expose a plurality of metal lands of the metal layer;
a center cavity enclosed between the bottom laminate substrate, the laminate window frame and the top substrate to house at least one die;
interconnection patterns included in the bottom laminate substrate, the laminate window frame and the center cavity, wherein the interconnection patterns provide electrical coupling between the metal layer, the at least one die, and a plurality of conductive bumps disposed on a bottom surface of the bottom laminate substrate; and
a top package mounted on top of the top substrate, wherein the top package is electrically coupled to the plurality of metal lands.

19. The device of claim 18, wherein a height of the device is less than or equal to 1.4 millimeters.

20. The device of claim 18, wherein the at least one die is one of one of a microprocessor, a digital signal processor, a radio frequency chip, a memory, a microcontroller, and a system-on-a-chip or a combination thereof.
